(19) United States
(12) Patent Application Publication
(10) Pub. No.: US 2025/0246532 A1
(43) Pub. Date: Jul. 31, 2025

(54) SUBSTRATES INCLUDING RAISED INTERCONNECTS DISPOSED ON A DIE-SIDE SURFACE TO SUPPORT INCREASED INTERCONNECT DENSITY AND RELATED METHODS

(71) Applicant: QUALCOMM Incorporated, San Diego, CA (US)

(72) Inventors: Manuel Aldrete, Encinitas, CA (US); Aniket Patil, San Diego, CA (US); Kuiwon Kang, San Diego, CA (US)

(21) Appl. No.: 18/426,691

(22) Filed: Jan. 30, 2024

(51) Int. Cl. H01L 23/498; H01L 21/48; H01L 23/00

(52) U.S. Cl. CPC H01L 23/49838; H01L 21/4857; H01L 23/49811; H01L 23/49822; H01L 24/16; H01L 2224/16225

(57) ABSTRACT

A plurality of surface interconnects is disposed in a surface interconnect layer on a first surface of a substrate. The surface interconnects extend between a first area and a second area. In some examples, the first area may be configured to couple to an integrated circuit die and the second area may include package contacts. In the second area, a dielectric layer is disposed on the surface interconnect layer, a plurality of raised interconnects are disposed on the dielectric layer, and the raised interconnects are coupled to the surface interconnects through the dielectric layer. The raised interconnects may provide parallel paths for signals propagating through the surface interconnects between the first area and the second area. The raised interconnects may allow surface interconnects to be narrowed and disposed with increased density on the substrate without increasing resistance for signals propagating between the first area and the second area.

### BACKGROUND

### I. Field of the Disclosure

The technology of the disclosure relates generally to package substrates and, more particularly, to reducing the area occupied by interconnects on a package substrate.

### II. Background

Integrated circuits (ICs) and other components provide electronic devices with functionalities that are ubiquitous in modern life. ICs and other components are disposed on substrates in packages to interconnect the components in circuits and physically secure them inside an electronic device. There is an ongoing effort to reduce the sizes of IC packages to increase the amount of function that can fit within an electronic device, which requires that, in addition to reductions to the sizes of ICs and other components, the package substrates on which they are disposed also need to be reduced in size. However, there are challenges associated with reducing the size of a package substrate without changing a level of functionality provide therein and/or reducing the number of input/output signals of the package substrate. For example, a peripheral area around an IC on a surface of a substrate includes signal interconnects (“surface interconnects”) to couple the IC to other components and to package interconnects (e.g., solder ball/pillar type interconnects) in the peripheral area. The package interconnects couple the substrate to an external circuit. As the size of the substrate is reduced, the peripheral area is reduced, leaving less area for the interconnects. To address this problem, the signal interconnects and package interconnects themselves can be reduced in area (e.g., narrower) and the center-to-center pitches can also be reduced. However, making these features smaller may have consequences that must also be addressed. For example, reduced wire widths increase interconnect impedance.

### SUMMARY

Aspects disclosed in the detailed description include substrates including raised interconnects disposed on a die-side surface to support increase interconnect density. A plurality of surface interconnects in a surface interconnect layer are disposed on a first surface of a substrate that may be employed in a package. The plurality of surface interconnects extends between a first area and a second area. In some examples, the first area may be configured to couple to an integrated circuit (IC) die, and the second area may include package contacts. In the second area, a dielectric layer is disposed on the surface interconnect layer, a plurality of raised interconnects are disposed on the dielectric layer, and the raised interconnects are coupled to the surface interconnects. In some examples, the plurality of raised interconnects provides parallel paths for signals propagating through the plurality of surface interconnects between the first area and the second area. In some examples, the raised interconnects allow the surface interconnects to be narrowed and disposed at increased interconnect density without increasing resistance for signals propagating between the first area and the second area.

In this regard, in one exemplary aspect, a substrate is disclosed. The substrate includes a surface interconnect layer comprising a plurality of surface interconnects extending between a first area and a second area on a first surface, a dielectric layer disposed on the surface interconnect layer in the second area, and a raised interconnect layer disposed on the dielectric layer and comprising a plurality of raised interconnects coupled to the plurality of surface interconnects through the dielectric layer.

In another exemplary aspect, a package is disclosed. The package includes a first IC die disposed in a first area of a first surface of a package substrate, a surface interconnect layer comprising a plurality of surface interconnects coupled to the first IC die and extending to a second area on the first surface of the package substrate, a dielectric layer disposed on the surface interconnect layer in the second area of the package substrate, and a raised interconnect layer disposed on the dielectric layer and comprising a plurality of raised interconnects coupled to the plurality of surface interconnects through the dielectric layer.

In another exemplary aspect, a method of fabricating a package is disclosed. The method includes forming a package substrate a surface interconnect layer comprising a plurality of surface interconnects extending between a first area and a second area of a first surface of the package substrate, disposing a first IC die in the first area and coupled to the plurality of surface interconnects, forming a dielectric layer on the surface interconnect layer in the second area, and forming a raised interconnect layer on the dielectric layer and comprising a plurality of raised interconnects coupled to the plurality of surface interconnects through the dielectric layer.

### BRIEF DESCRIPTION OF THE DRAWINGS

FIG. 1A is a plan view of a substrate, including a first area configured to couple to an integrated circuit (IC) die, a second area including surface interconnects, and a third area including package interconnects;

FIG. 1B is a close-up view of a region including the second area and the third area of the substrate in FIG. 1A in which the surface interconnects transition from first, larger dimensions to second, smaller dimensions;

FIG. 2 is a cross-sectional side view of a first integrated circuit (IC) package comprising an IC disposed on a package substrate and interconnects coupling the IC to a peripheral area;

FIG. 3 is a cross-sectional side view of a package substrate as shown in FIG. 2, including a surface interconnect layer and a second interconnect layer coupled to the surface interconnect layer to reduce impedance;

FIG. 4 is a cross-sectional side view of an exemplary IC package comprising an IC disposed on a package substrate and a plateau in the peripheral area, including a raised interconnect layer coupled to the IC through a surface interconnect layer;

FIG. 5 is a cross-sectional side view of an exemplary plateau in a peripheral area of a package substrate, such as in FIG. 4, providing a first raised interconnect in a raised interconnect layer to provide another path, parallel to a first surface interconnect, to reduce signal impedance;

FIG. 6 is a flowchart of an exemplary fabrication process of fabricating a substrate, including a raised interconnect layer in a peripheral area to reduce package interconnect dimensions to reduce a peripheral area of the package substrate without increased signal impedance;

FIG. 7 is a cross-sectional side view of a second IC package, including a first IC on a first package substrate and a second substrate stacked on the first package substrate to couple the first IC to a second IC or another external circuit;

FIG. 8 is a cross-sectional side view of a second exemplary IC package, including a second substrate for stacking a second IC on a first IC, including a plateau in a peripheral area with (e.g., vertical) package interconnects extending from a raised interconnect layer to a second package substrate;

FIGS. 9A and 9B are a cross-sectional side view and a top plan view, respectively, of one example of an IC package including an IC disposed in a first area of a package substrate, a third area along an edge of the package substrate, and a raised interconnect layer in a second area between the first area and the third area;

FIGS. 10A and 10B are a cross-sectional side view and a top plan view, respectively, of one example of an IC package including a raised interconnect layer in a peripheral area that extends from an IC package to an edge of the package substrate;

FIGS. 11A and 11B are a cross-sectional side view and a top plan view, respectively, of one example of an IC package including a raised interconnect layer in a peripheral area spaced from an IC package by an area, not including the raised interconnect layer;

FIGS. 12A-12F are a flowchart illustrating another exemplary fabrication process of fabricating an IC package, including a raised interconnect layer on a package substrate to reduce package interconnect dimensions and signal interconnect area without increased impedance, including but not limited to the package substrates and IC packages in FIGS. 4 and 8-11B;

FIGS. 13A-13F are exemplary fabrication stages during the fabrication of a package substrate, including a raised interconnect layer to reduce package interconnect dimensions and signal interconnect area without increased impedance according to the exemplary fabrication process in FIGS. 12A-12F;

FIG. 14 is a block diagram of an exemplary processor-based system that can include IC packages, including the package substrate including the raised interconnect layer to reduce package interconnect dimensions and reduce impedance of signal interconnects in FIGS. 4 and 8-11B and according to but not limited to, any of the exemplary fabrication processes in FIGS. 6 and 12A-12F; and

FIG. 15 is a block diagram of an exemplary wireless communication device that includes radio-frequency (RF) components that can include the IC package including a package substrate including a raised interconnect layer to reduce package interconnect dimensions and reduce impedance of signal interconnects coupled to an IC on the package substrate including but not limited to the package substrate in FIGS. 4 and 8-11B and according to but not limited to, any of the exemplary fabrication processes in FIGS. 6 and 12A-12F.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed in the detailed description include substrates including raised interconnects disposed on a die-side surface to support increase interconnect density. A plurality of surface interconnects in a surface interconnect layer are disposed on a first surface of a substrate that may be employed in a package. The plurality of surface interconnects extends between a first area and a second area. In some examples, the first area may be configured to couple to an integrated circuit (IC) die and the second area may include package contacts. In the second area, a dielectric layer is disposed on the surface interconnect layer, a plurality of raised interconnects are disposed on the dielectric layer, and the raised interconnects are coupled to the surface interconnects. In some examples, the plurality of raised interconnects provides parallel paths for signals propagating through the plurality of surface interconnects between the first area and the second area. In some examples, the raised interconnects allow the surface interconnects to be narrowed and disposed at increased interconnect density without increasing resistance for signals propagating between the first area and the second area.

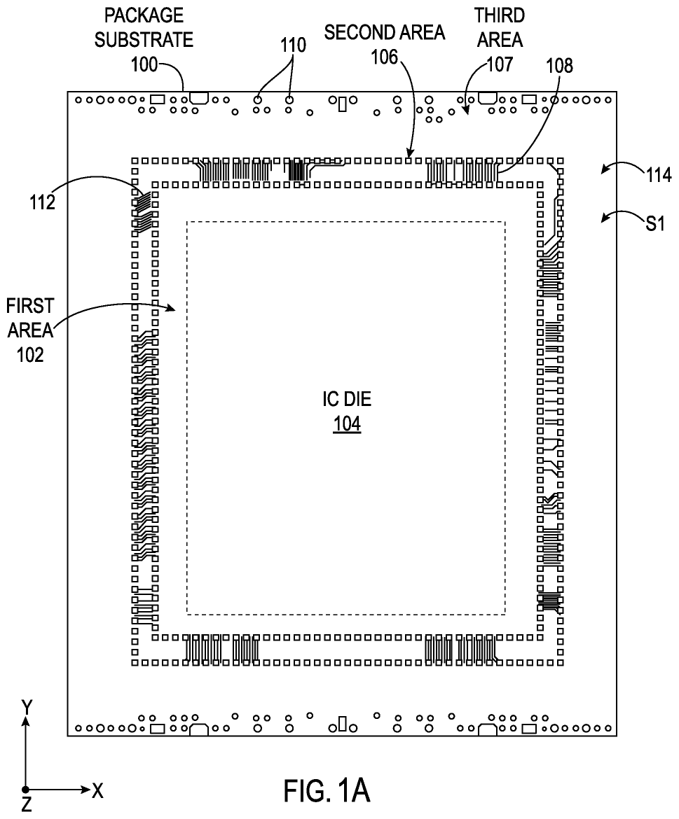

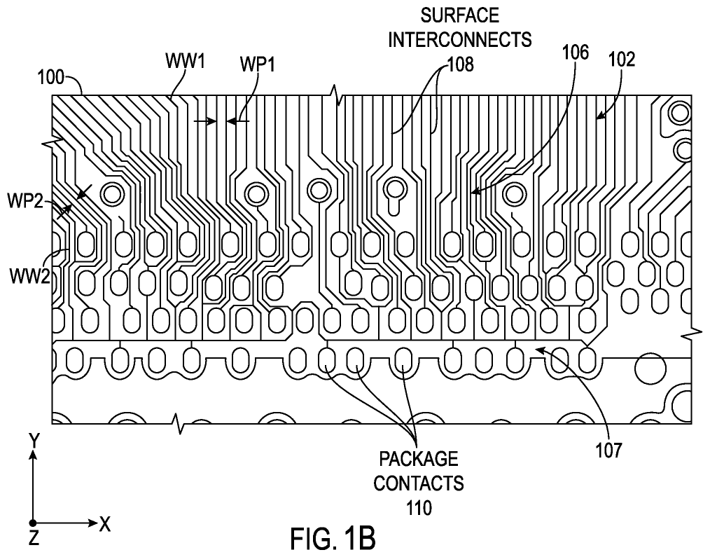

FIG. 1A is a plan view of a package substrate 100 (“substrate 100”), including a first area 102 configured to couple to an IC die 104 and a peripheral area including a second area 106 and a third area 107. The second area 106 includes surface interconnects 108, to electrically couple the IC die 104 to package contacts 110 in the third area 107. The second area 106 and the third area 107 may overlap with each other. In this context, the term “surface interconnect” may refer to conductive (e.g., metal) wires or traces in an interconnect layer 112 on a surface 114 of a first side S1 of the package substrate 100, on which the IC die 104 may be attached. The surface 114 may be referred to herein as a “die-side surface” because the surface 114 is configured to couple to the IC die 104 The package contacts 110 may be contacts on which a package interconnect, such as a solder ball or pillar type interconnect (e.g., vertical interconnect), for example, may be disposed to electrically couple a surface interconnect 108 to an interposer (not shown) or external substrate of another package, which may include another IC or other component(s) configured to couple to the IC die 104. The surface interconnects 108 may also be referred to as signal interconnects 108.

Die interconnects (not shown) (e.g., a ball grid array) coupling the IC die 104 to the surface interconnects 108 in the first area 102 of the substrate 100 have a first wire width WW1 and are disposed at a first wire pitch WP1 (center-to-center distance), as seen in FIG. 1B. In contrast, in the peripheral area of the substrate 100 on or outside a perimeter of the IC die 104, which includes the second area 106, there may be different interconnect density to accommodate the number of the surface interconnects 108 that extend through the second area 106 to the third area 107. To achieve greater interconnect density, the surface interconnects 108 are reduced in width (narrowed) to a second wire width WW2 and are positioned closer together at a second wire pitch (center-to-center distance) WP2. The need for increased interconnect density is exacerbated by the pressure to reduce the sizes of packages in electronic devices.

FIG. 1B is a close-up view of a portion of the package substrate 100 in FIG. 1A, including first area 102 in which the surface interconnects 108 have first dimensions (wire width WW1 and first wire pitch WP1), and the second area 106 in which the surface interconnects 108 transition to the second, reduced wire widths WW2 and reduced wire pitches WP2 to achieve greater interconnect density and couple to the package contacts 110 in the third area 107. That is, to fit as many of the surface interconnects 108 and package contacts 110 as possible within a smaller area, wire pitches, and wire widths are reduced in the second area 106.

A problem with reducing wire widths without also increasing wire height is that the cross-sectional area of a wire (e.g., a surface interconnect 108) is reduced, which can increase impedance and slow down the speed of signal propagation through the surface interconnects 108, in addition to increasing power consumption.

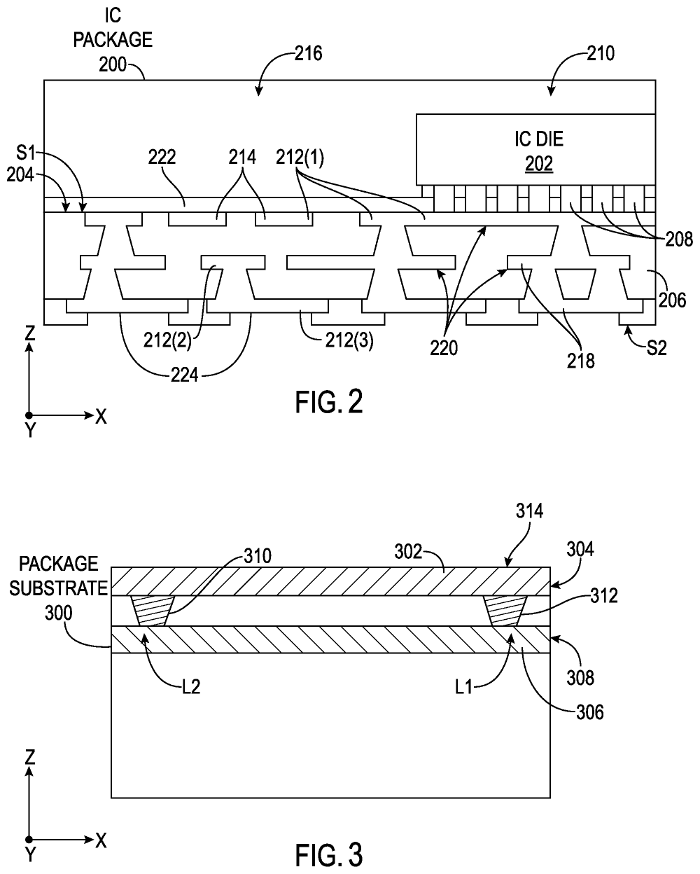

FIG. 2 is a cross-sectional side view of an IC package 200 comprising an IC die or chip 202 disposed on a surface 204 on a first side S1 of a package substrate 206 (“substrate 206”) and further comprising die interconnects 208 coupling the IC die 202 in a first area 210 of the package substrate 206 to a surface interconnect layer 212(1) including surface interconnects 214 that extend from the first area 210 to a second area 216 outside the first area 210. The surface interconnect layer 212(1) may also be coupled to interconnect layers 212(2)-212(3), below the surface 204, which includes substrate interconnects 218. In this example, the surface interconnects 214 in the first interconnect layer 212(1) on the surface 204 are coupled directly to the IC die 202 by the die interconnects 208. Signals 220 generated in or received in the IC die 202 propagate through the surface interconnects 214 in the interconnect layer 212(1). In addition, to reduce the impedance seen by the signals 220, the surface interconnects 214 may be coupled to corresponding substrate interconnects 218 in the interconnect layer 212(2). That is, in some examples, there may be substrate interconnects 218 in the interconnect layer 212(2) corresponding to the surface interconnects 214 in the interconnect layer 212(1) to provide parallel paths between the IC die 202 in the first area 210 and the second area 216 to reduce resistance or impedance for the signals 220.

In this example, an insulating layer 222 is disposed on the surface interconnects 214. Package contacts 224 in the interconnect layer 212(3) on a second side S2 of the package substrate 206 are provided to electrically couple the IC die 202 to an external circuit.

FIG. 3 is a cross-sectional side view of a package substrate 300, including a surface interconnect 302 in a surface interconnect layer 304 coupled to a substrate interconnect 306 in another interconnect layer 308. The substrate interconnect 306 is employed to provide a parallel path to conduct signal 314 propagating through the surface interconnect 302 from a first location L1 to a second location L2. The package substrate 300 includes at least two vertical connections 310 and 312 (vertical interconnect accesses (vias)) to electrically couple the surface interconnect 302 and the substrate interconnect 306. Including the first via 310 in the first location L1 and the second via 312 in the second location L2 of the package substrate 300 allows the signal 314 to propagate between the first location L1 and the second location L2 by way of both the surface interconnect 302 and the substrate interconnect 306, thereby increasing a conductive cross-section through which the signal 314 propagates, which reduces impedance for the signal 314 between the first location L1 and the second location L2.

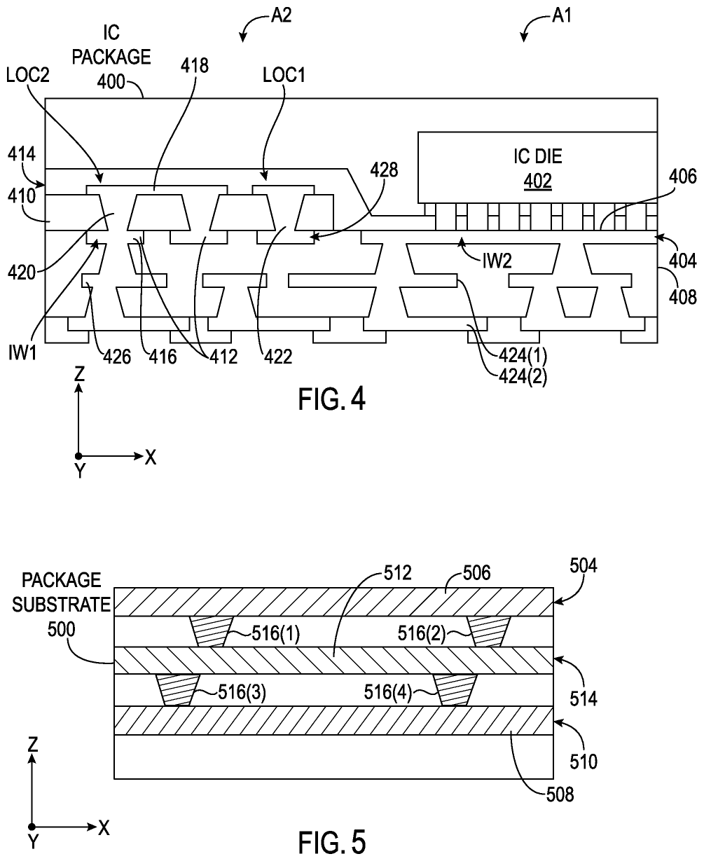

FIG. 4 is a cross-sectional side view of an exemplary IC package 400 comprising an IC die 402 disposed on a surface interconnect layer 404 in a first area A1 of a first surface 406 of a package substrate 408 (“substrate 408”). The first surface 406 includes the first area A1 and a second area A2, which may be outside of and along a perimeter of the first area A1. The surface interconnect layer 404 is among a plurality of interconnect layers of the package substrate 408 and includes a plurality of surface interconnects 412. The plurality of surface interconnects 412 includes a first surface interconnect 416, which may be coupled to the IC die 402 and extends between the first area A1 and the second area A2 on the first surface 406 (not shown).

In an exemplary aspect, the IC package 400 also includes a dielectric layer 410 disposed on the surface interconnect layer 404 in the second area A2 of the first surface 406. The dielectric layer 410 is not disposed in the first area. A raised interconnect layer 414, comprising a plurality of raised interconnects 417, is disposed on the dielectric layer 410. The plurality of raised interconnects 417 is coupled to the plurality of surface interconnects 412 through the dielectric layer 410. The first surface interconnect 416 may extend from a first location LOC1 in the second area A2 to a second location LOC2 in the second area A2. The raised interconnect layer 414 comprises a first raised interconnect 418 that is coupled to the first surface interconnect 416 in the first location LOC1 and also in the second location LOC2. For example, the package substrate 408 may include vias 420 and 422 in the first and second locations LOC1 and LOC2, respectively, with each of the vias 420 and 422 electrically coupling the first raised interconnect 418 to the first surface interconnect 416.

The package substrate 408 includes substrate interconnect layers 424(1) and 424(2). Each of the surface interconnect layer 404, the raised interconnect layer 414, and the substrate interconnect layers 424(1) and 424(2) are conductive layers that may be formed of a metal, such as copper or other appropriate material. The substrate interconnect layer 424(1) may also include a substrate interconnect 426 corresponding to the first surface interconnect 416 to provide a parallel electrical path from the first location LOC1 to the second location LOC2. In this context, “parallel” does not mean that the paths take a same route but rather that they both connect to the first location LOC1 and the second location LOC2. The substrate interconnect 426 may provide a path for a signal 428 propagating from the first location LOC1 to the second location LOC2, where such path is provided in addition to the first surface interconnect 416 to reduce the signal impedance compared to the first surface interconnect 416 alone.

However, as manufacturers reduce package sizes, the area of the package substrate 408 is reduced, which may include a reduction of the second area A2 without necessarily reducing the first area A1. Accordingly, the density of the plurality of surface interconnects 412 increases from the first area A1 to the second area A2. To accomplish this density increase, the plurality of surface interconnects 412 are reduced in width (narrowed) and disposed at a smaller center-to-center distance (as shown in FIG. 1B) in the second area A2. This reduction in width (without an increase in height) causes an increase in impedance to the signal 428 propagating through the first surface interconnect 416, for example. In this example, the substrate interconnect 426 provides a first path parallel to the first surface interconnect 416 to reduce impedance for the signal 428. In addition, the first raised interconnect 418 in the raised interconnect layer 414 provides a second parallel path to enable further reduction in impedance, which may account for further decreases in interconnect dimensions (e.g., wire widths) in future generations of technology. Thus, as described with reference back to FIG. 1B, a first center-to-center distance or pitch WP1 between two adjacent surface interconnects of the plurality of surface interconnects 412 in the first area A1 is greater than a second center-to-center distance (pitch) WP2 between the two adjacent surface interconnects in the second area A2. In addition, a first interconnect width (e.g., wire width) IW1 of the plurality of surface interconnects 412 in the first area A1 is greater than a second width IW2 of the plurality of surface interconnects 412 in the second area A2.

FIG. 5 is a cross-sectional side view of an exemplary package substrate 500 having a raised interconnect layer 504 including a first raised interconnect 506. The first raised interconnect 506 is provided, in addition to the first substrate interconnect 508 in a substrate interconnect layer 510, for the purpose of reducing impedance by providing another parallel path for a signal propagating in a first surface interconnect 512 in a surface interconnect layer 514. The package substrate 500 includes vias 516(1)-516(2) between the surface interconnect layer 514 and the raised interconnect layer 504, and vias 516(3)-516(4) between the surface interconnect layer 514 and the substrate interconnect layer 510 to provide parallel paths. Coupling the first surface interconnect 512 in the third direction (e.g., Z-axis direction) to both the raised interconnect layer 504 and the substrate interconnect layer 510 provides alternate signal paths parallel to the surface interconnect layer 514, thereby reducing signal impedance.

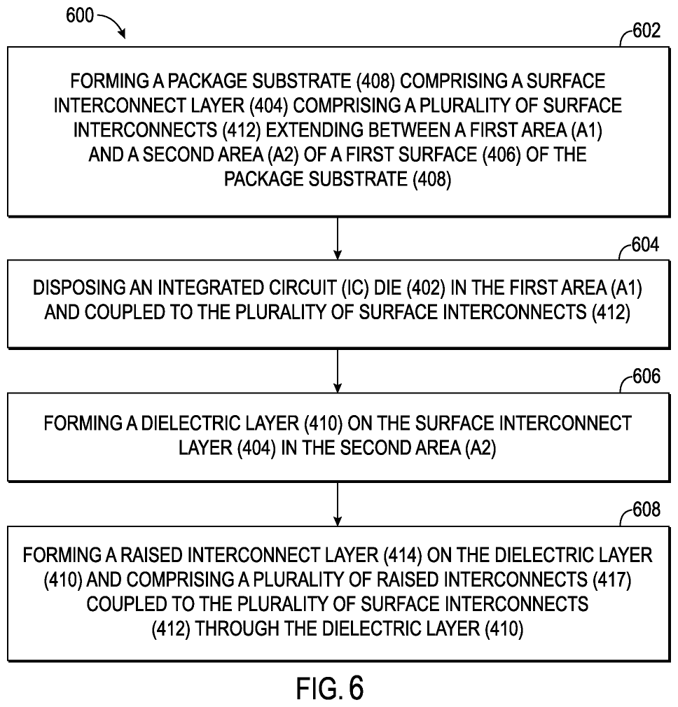

FIG. 6 is a flowchart of an exemplary fabrication method 600 of fabricating a package substrate. The fabrication process or method 600 is discussed with regard to the package substrate 408 in the IC package in FIG. 4, but note that the fabrication method 600 in FIG. 6 is not limited to fabricating the package substrate 408 in FIG. 4.

The method 600 comprises forming a package substrate 408 comprising a surface interconnect layer 404 comprising a plurality of surface interconnects 412 extending between a first area A1 and a second area A2 of a first surface 406 of the package substrate 408 (block 602). The method further comprises disposing a first integrated circuit (IC) die 402 in the first area A1 and coupled to the plurality of surface interconnects 412 (block 604). forming a dielectric layer 410 on the surface interconnect layer 404 in the second area A2 (block 606). The method further comprises forming a raised interconnect layer 414 on the dielectric layer 410 and comprising a plurality of raised interconnects coupled to the plurality of surface interconnects 412 through the dielectric layer 410 (block 608).

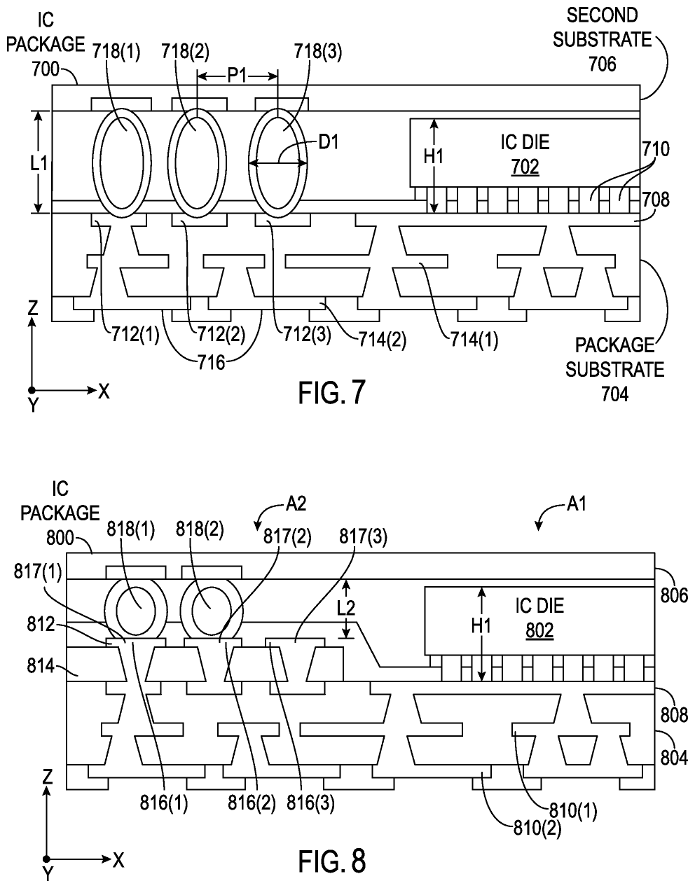

FIG. 7 is a cross-sectional side view of an IC package 700, including a first IC die 702 on a first package substrate 704 and a second substrate 706 stacked on the first package substrate 704 to couple the first IC die 702 to a second IC (not shown) or another external circuit. The first IC die 702 is coupled to a surface interconnect layer 708 by die interconnects 710. The surface interconnect layer 708 includes surface interconnects 712(1)-712(3) that may be coupled to substrate interconnect layers 714(1) and 714(2) to provide electrical paths parallel to the surface interconnects 712(1)-712(3). The surface interconnects 712(1)-712(3) in this example are coupled to package contacts 716 and to package interconnects 718(1)-718(3). The package interconnects 718(1)-718(3) are employed to couple the first IC die 702 to the second substrate 706. The second substrate 706 is spaced from the surface interconnect layer 708 in the Z-axis direction by a distance L1, and the first IC die 702 is between the first package substrate 704 and the second substrate 706. The first IC die 702 extends a height H1 above the surface interconnect layer 708, so the distance L1 must be equal to or greater than the height H1. Thus, package interconnects 718(1)-718(3) extend the distance L1 in the Z-axis direction and have corresponding diameters D1 in the X-axis and Y-axis directions. For example, the package interconnects 718(1)-718(3) may be solder balls or pillars having a particular aspect ratio between height and diameter. Due to the diameters D1 and spacing considerations, there is a limitation on a center-to-center distance, or pitch P1, of the package interconnects 718(1)-718(3), which limits the density of the package interconnects 718(1)-718(3) between the first package substrate 704 and the second substrate 706. A limit to the density of the package interconnects 718(1)-718(3) may prevent further reduction in the area of the IC package 700.

FIG. 8 is a cross-sectional side view of a second exemplary IC package 800, including a first IC die 802 in a first area A1 on a first package substrate 804 and a second substrate 806 stacked on the first package substrate 804 to couple the first IC die 802 to a second IC (not shown) or another external circuit. The IC package 800 includes a surface interconnect layer 808 coupled to the first IC die 802, as well as substrate interconnect layers 810(1) and 810(2). The IC package 800 includes a raised interconnect layer 812 disposed on a dielectric layer 814, which is disposed on the surface interconnect layer 808 in a second area A2. The raised interconnect layer 812 includes raised interconnects 816(1)-816(3), which may include package contacts 817(1)-817(3). In this example, the package contacts 817(1) and 817(2) on the dielectric layer 814 are coupled to the second substrate 806 through package interconnects 818(1)-818(2). It should be understood that the number of package contacts 817(1)-817(3) shown in FIG. 8 is not intended to be limiting or necessarily representative of a number that may be disposed in the area A2 or between the first IC die 802 and an edge of the first package substrate 804.

As discussed previously, the raised interconnects 816(1)-816(3) are provided for the purpose of reducing impedance by providing alternative paths for signals to propagate parallel to surface interconnects 820 in the surface interconnect layer 808. However, in an additional exemplary aspect, a distance L2 between the raised interconnect layer 812 and the second substrate 806 may be less than the height H1 of the first IC die 802 above the surface interconnect layer 808. Consequently, the package interconnects 818(1) and 818(2) may be reduced in height compared to the package interconnects 718(1)-718(3) in FIG. 7. Since the package interconnects 818(1) and 818(2) may be reduced in height, they may also be reduced in diameter while maintaining a same aspect ratio, which allows a smaller pitch or separation in the X-axis and Y-axis directions, further allowing a greater density of the package interconnects 818(1) and 818(2) between the first package substrate 804 and the second substrate 806. In this manner, the raised interconnect layer 812 in the second area A2 contributes to efforts to reduce the size of IC packages such as the IC package 800 by reducing impedance in signal paths that are narrowed to achieve greater density in a package substrate and by reducing the dimensions of (vertical) package interconnects to increase package interconnect density.

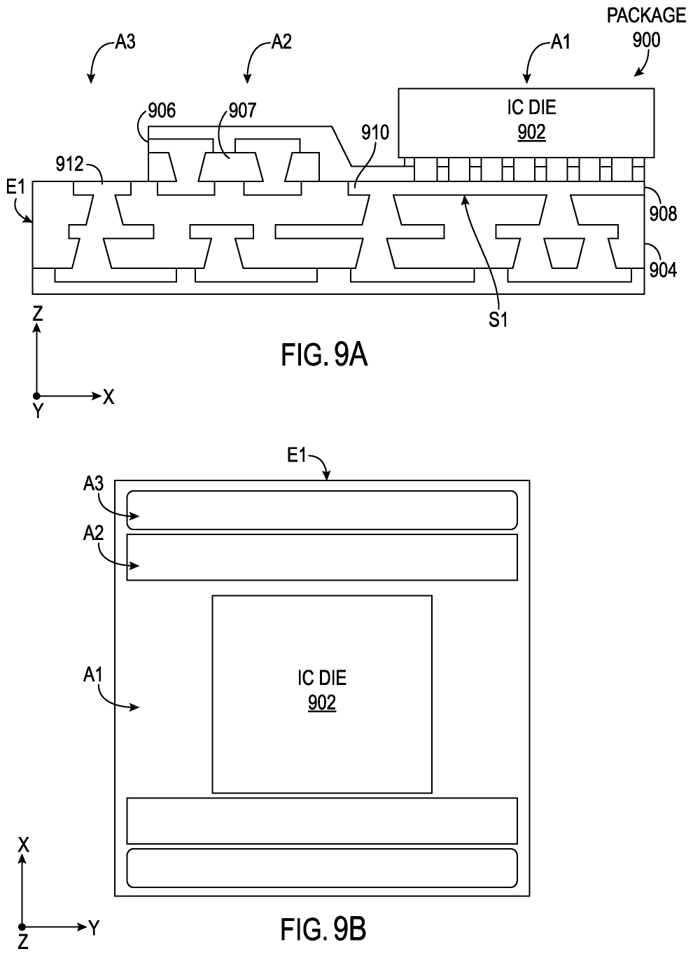

FIG. 9A is a cross-sectional side view of another example of an IC package 900, including an IC die 902 disposed in a first area A1 of a package substrate 904. The package substrate 904 includes a raised interconnect layer 906 disposed on a dielectric layer 907 in a second, peripheral area A2. The second area A2 is on (e.g., around) a perimeter of the first area A1 and between the first area A1 and a third area A3, which is along an edge E1 of the package substrate 904. The third area A3, does not include the raised interconnect layer 906 or the dielectric layer 907. FIG. 9B is a plan view of the IC package 900 in FIG. 9A.

In this example, the dielectric layer 907 and the raised interconnect layer 906 are disposed on a surface interconnect layer 908 and may be employed to reduce impedance for a signal S1 propagating through a surface interconnect 910 in the surface interconnect layer 908. However, package contacts 912 in this example are formed on the surface interconnect 910 in the third area A3 and not formed on the dielectric layer 907. Thus, a package interconnect density may not be reduced in the third area A3 in this example.

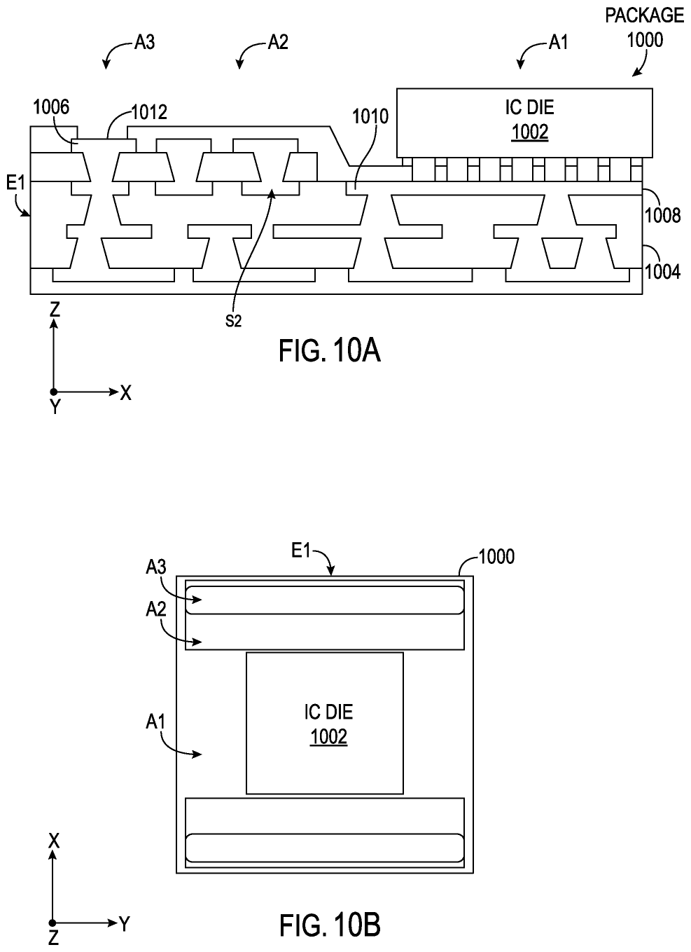

FIG. 10A is a cross-sectional side view of another example of an IC package 1000 including an IC die 1002 disposed in a first area A1 of a package substrate 1004. The package substrate 1004 includes a raised interconnect layer 1006 in a second area A2, which includes a third area A3 that extends along an edge E1 of the package substrate 1004. The second area A2, in this example, is between the first area A1 and the edge E1. FIG. 10B is a plan view of the IC package 1000 in FIG. 10A.

In this example, the raised interconnect layer 1006 is disposed on a surface interconnect layer 1008 that may extend from the first area A1 to the edge E1. The raised interconnect layer 1006 may be employed to reduce impedance for a signal S2 propagating through a surface interconnect 1010 in the surface interconnect layer 1008 in the second area A2, as discussed above. The signal S2 is representative of any number of signals that may propagate through the surface interconnect layer 1008. In addition, the raised interconnect layer 1006 in this example includes, in the third area A3, a package contact 1012 on which a package interconnect (not shown) having a reduced height may be formed for coupling another substrate to the IC package 1000. The package contact 1012 may be included among many package contacts provided in the third area A3 of the package substrate 1004 for coupling to another substrate. In this example, the raised interconnect layer 1006 provides the benefit of increasing the density of package interconnects (not shown) as well as reducing impedance for signals in the surface interconnect layer 1008.

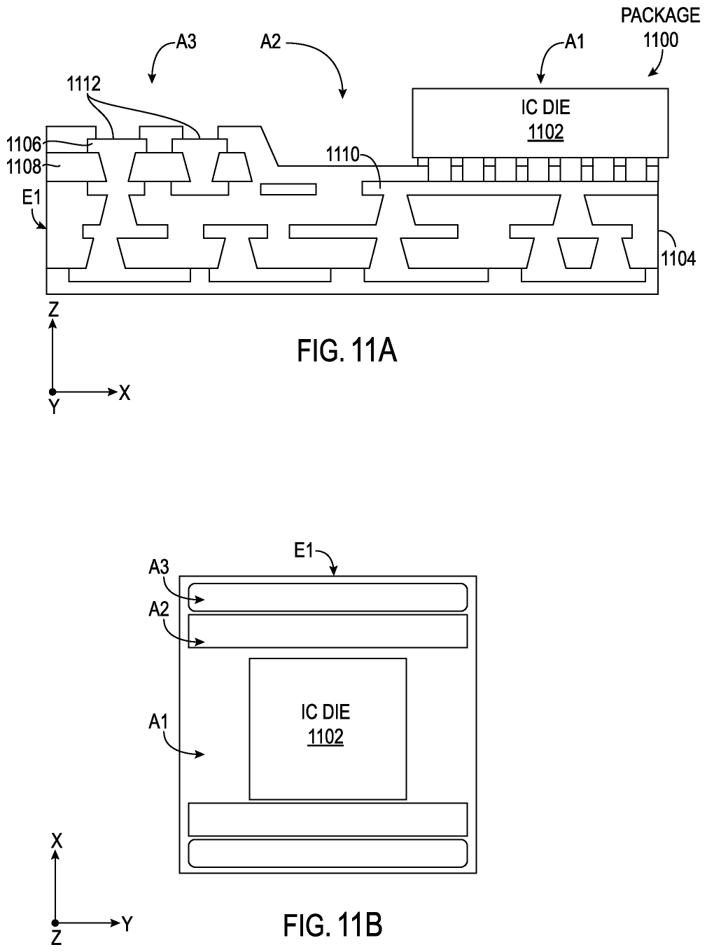

FIG. 11A is a cross-sectional side view of another example of an IC package 1100, including an IC die 1102 disposed in a first area A1 of a package substrate 1104. The package substrate 1104 includes a raised interconnect layer 1106 disposed on a dielectric layer 1108 in a third, peripheral area A3 along an edge E1 of the package substrate 1104. The package substrate 1104 includes a second area A2, which is between the area A1 and the peripheral area A3. FIG. 11B is a plan view of the IC package 1100 in FIG. 11A.

In this example, the raised interconnect layer 1106 is disposed on a dielectric layer 1108. The dielectric layer 1108 is disposed on the surface interconnect layer 1110 that extends through the second area A2 and the third area A3 to the edge E1. The raised interconnect layer 1106 may include package contacts, such as package contact 1112, on which package interconnects (not shown) having a reduced height may be formed at increased density and employed for coupling another substrate to the IC package 1100. In this example, the raised interconnect layer 1106 is not provided in the second area A2.

Other fabrication processes can also be employed to fabricate IC packages, including package substrates, including raised interconnect layers that provide reduced impedance for signals in a surface interconnect layer of a package substrate and also provide for reduced package interconnect dimensions that allow increased package interconnect density, including but not limited to the IC packages 800, 900, 1000, and 1100 in FIGS. 8-11B.

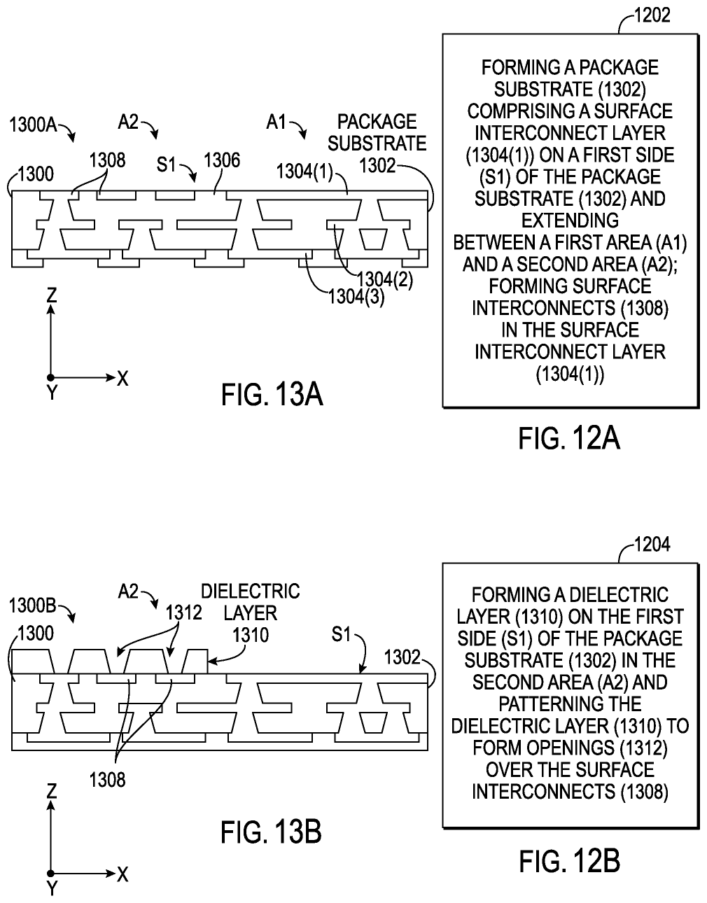

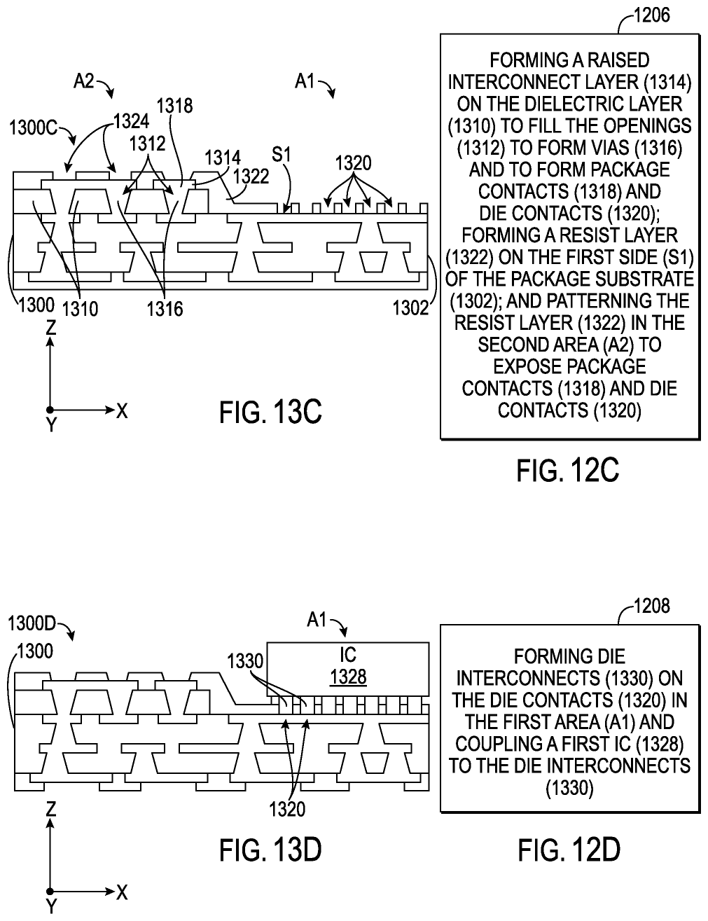

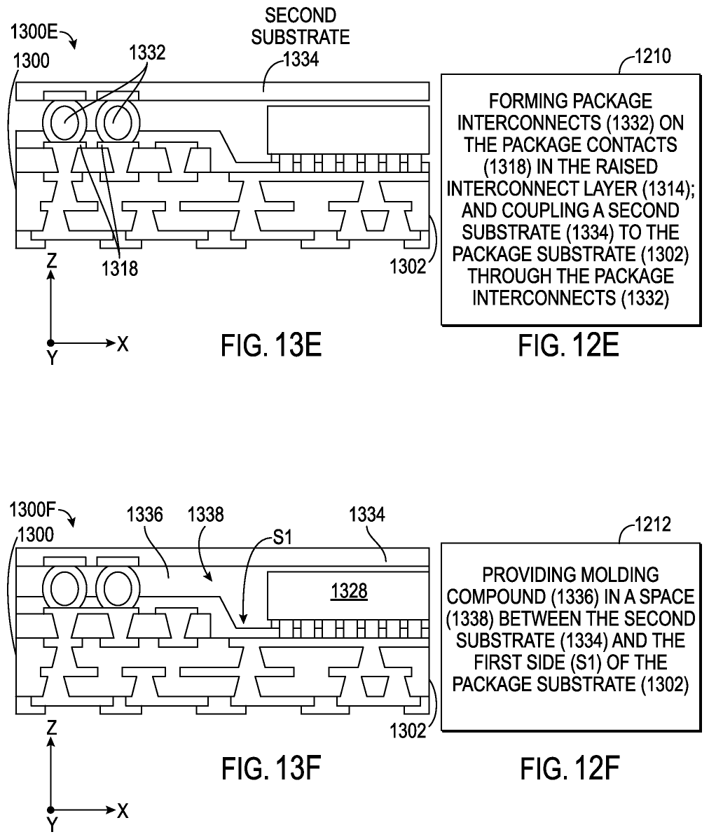

In this regard, FIGS. 12A-12F are a flowchart illustrating another exemplary fabrication process 1200 of fabricating an IC package 1300, including a raised interconnect layer on a package substrate to reduce package interconnect dimensions and reduce impedance of signal interconnects coupled to an IC in the IC package, including but not limited to the IC packages 800-1100 in FIGS. 8-11B.

FIGS. 13A-13F are exemplary fabrication stages 1300A-1300F during fabrication of the IC packages, including package substrates, including raised interconnect layers that provide reduced impedance for signals in a surface interconnect layer of the package substrate and also provide for reduced package interconnect dimensions that allow increased package interconnect density according to the fabrication process 1200 in FIGS. 12A-12F.

In this regard, as shown in the fabrication stage 1300A in FIG. 13A, the fabrication process 1200 of the IC package 1300 begins with forming a package substrate 1302 comprising a plurality of interconnect layers 1304(1)-1304(X) (where X=3 in this example). The plurality of interconnect layers 1304(1)-1304(X) may be disposed in a dielectric medium 1306, for example. Step 1202 in the fabrication process includes forming a package substrate 1302 comprising a surface interconnect layer 1304(1) on a first side S1 of the package substrate 1302 and extending between a first area A1 (in which an IC die (see FIG. 13D) may be coupled to the package substrate 1302) and a second area A2, which may be outside or peripheral to the first area A1. Step 1202 may further include forming c surface interconnects 1308 in the surface interconnect layer 1304(1). In some examples, the package contacts 1308 may be coupled to interconnects in one or more surface interconnect layers 1304(2)-1304(X). Features described above and labeled in FIG. 13A may be similarly labeled in FIGS. 13B-13F but not further referred to herein.

A fabrication step 1204 in the fabrication process 1200 is illustrated in the fabrication stage 1300B in FIG. 13B. The fabrication step 1204 comprises forming a dielectric layer 1310 on the first side S1 of the package substrate 1302 in the second area A2 and patterning the dielectric layer 1310 to form openings 1312 over the surface interconnects 1308 in which vias (not shown) may be formed.

A fabrication step 1206 in the fabrication process 1200 is illustrated in the fabrication stage 1300C in FIG. 13C. The fabrication step 1206 comprises forming a raised interconnect layer 1314 on the dielectric layer 1310 including filling the openings 1312 to form vias 1316, and to form package contacts 1318 and die contacts 1320. The fabrication step 1206 also comprises forming a resist layer 1322 on the first side S1 of the package substrate 1302 and patterning the resist layer 1322 in the second area A2 to form openings 1324 to expose the package contacts 1318. The resist layer 1322 may also be patterned in the first area A1 to form contact locations 1326 for coupling to an IC 1328 (see FIG. 13D). In an alternative example, the openings 1324 may be formed in the resist layer 1322 in a later stage, such as fabrication stage 1300E.

A fabrication step 1208 in the fabrication process 1200 is illustrated in the fabrication stage 1300D in FIG. 13D. The fabrication step 1208 comprises forming die interconnects 1330 on the die contacts 1320 in the first area A1 and coupling the first IC 1328 to the die interconnects 1330.

Additional optional steps in the fabrication process 1200 are provided for forming a second embodiment of IC package 1300 including a second substrate (e.g., for IC stacking), as shown in FIGS. 13E and 13F. A fabrication step 1210 in the fabrication process 1200 is illustrated in the fabrication stage 1300E in FIG. 13E. The fabrication step 1210 comprises forming package interconnects 1332 on the package contacts 1318 in the raised interconnect layer 1314. The optional fabrication step 1210 further comprises coupling a second substrate 1334 to the package substrate 1302 through package interconnects 1332.

A fabrication step 1212 in the fabrication process 1200 is illustrated in the fabrication stage 1300F in FIG. 13F. The optional fabrication step 1212 comprises providing molding compound 1336 in a space 1338 between the second substrate 1334 and the first side S1 of the package substrate 1302.

Electronic devices, according to any aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

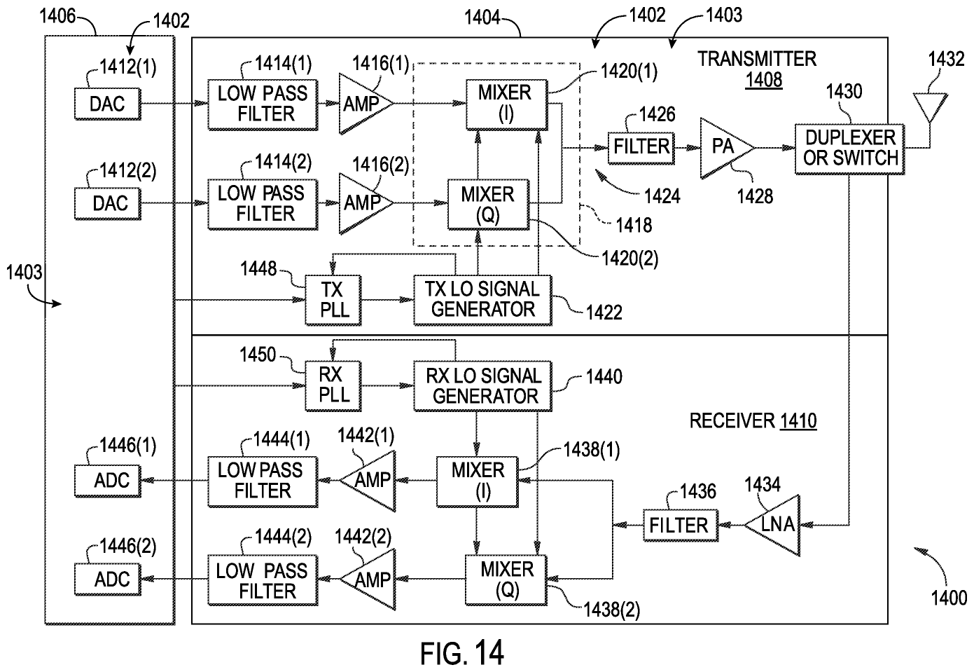

In this regard, FIG. 14 illustrates a block diagram of an exemplary wireless communications device 1400 that includes radio frequency (RF) components formed from one or more ICs 1402, wherein the communications device 1400 may include an IC package including a raised interconnect layer on a package substrate to reduce package interconnect dimensions and reduce impedance of signal interconnects coupled to an IC in the IC package, such as any of the IC packages 800, 900, 1000, and 1100 in FIGS. 8-11B. The wireless communications device 1400 may include or be provided as examples in any of the above-referenced devices. As shown in FIG. 14, the wireless communications device 1400 includes a transceiver 1404 and a data processor 1406. The data processor 1406 may include a memory to store data and program codes. The transceiver 1404 includes a transmitter 1408 and a receiver 1410, which support bi-directional communications. In general, the wireless communications device 1400 may include any number of transmitters 1408 and/or receivers 1410 for any number of communication systems and frequency bands. All or a portion of the transceiver 1404 may be implemented on one or more analog ICs, RF ICs (RFICs), mixed-signal ICs, etc.

The transmitter 1408 or the receiver 1410 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 1400 in FIG. 14, the transmitter 1408 and the receiver 1410 are implemented with the direct-conversion architecture.

In the transmit path, the data processor 1406 processes data to be transmitted and provides I and Q analog output signals to the transmitter 1408. In the exemplary wireless communications device 1400, the data processor 1406 includes digital-to-analog converters (DACs) 1412(1), 1412(2) for converting digital signals generated by the data processor 1406 into I and Q analog output signals, e.g., I and Q output currents, for further processing.

Within the transmitter 1408, lowpass filters 1414(1), 1414(2) filter the I and Q analog output signals, respectively, to remove undesired signals caused by the prior digital-to-analog conversion. Amplifiers (AMPs) 1416(1), 1416(2) amplify the signals from the lowpass filters 1414(1), 1414(2), respectively, and provide I and Q baseband signals. An upconverter 1418 upconverts the I and Q baseband signals with I and Q transmit (TX) local oscillator (LO) signals from a TX LO signal generator 1422 through mixers 1420(1), 1420(2) to provide an upconverted signal 1424. A filter 1426 filters the upconverted signal 1424 to remove undesired signals caused by the frequency upconversion and noise in a receive frequency band. A power amplifier (PA) 1428 amplifies the upconverted signal 1424 from the filter 1426 to obtain the desired output power level and provides a transmit RF signal. The transmit RF signal is routed through a duplexer or switch 1430 and transmitted via an antenna 1432.

In the receive path, the antenna 1432 receives signals transmitted by base stations and provides a received RF signal, which is routed through the duplexer or switch 1430 and provided to a low noise amplifier (LNA) 1434. The duplexer or switch 1430 is designed to operate with a specific receive (RX)-to-TX duplexer frequency separation, such that RX signals are isolated from TX signals. The received RF signal is amplified by the LNA 1434 and filtered by a filter 1436 to obtain a desired RF input signal. Downconversion mixers 1438(1), 1438(2) mix the output of the filter 1436 with I and Q RX LO signals (i.e., LO_I and LO_Q) from an RX LO signal generator 1440 to generate I and Q baseband signals. The I and Q baseband signals are amplified by AMPs 1442(1), 1442(2) and further filtered by lowpass filters 1444(1), 1444(2) to obtain I and Q analog input signals, which are provided to the data processor 1406. In this example, the data processor 1406 includes analog-to-digital converters (ADCs) 1446(1), 1446(2) for converting the analog input signals into digital signals to be further processed by the data processor 1406.

In the wireless communications device 1400 of FIG. 14, the TX LO signal generator 1422 generates the I and Q TX LO signals used for frequency upconversion, while the RX LO signal generator 1440 generates the I and Q RX LO signals used for frequency downconversion. Each LO signal is a periodic signal with a particular fundamental frequency. A TX phase-locked loop (PLL) circuit 1448 receives timing information from the data processor 1406 and generates a control signal used to adjust the frequency and/or phase of the TX LO signals from the TX LO signal generator 1422. Similarly, an RX PLL circuit 1450 receives timing information from the data processor 1406 and generates a control signal used to adjust the frequency and/or phase of the RX LO signals from the RX LO signal generator 1440.

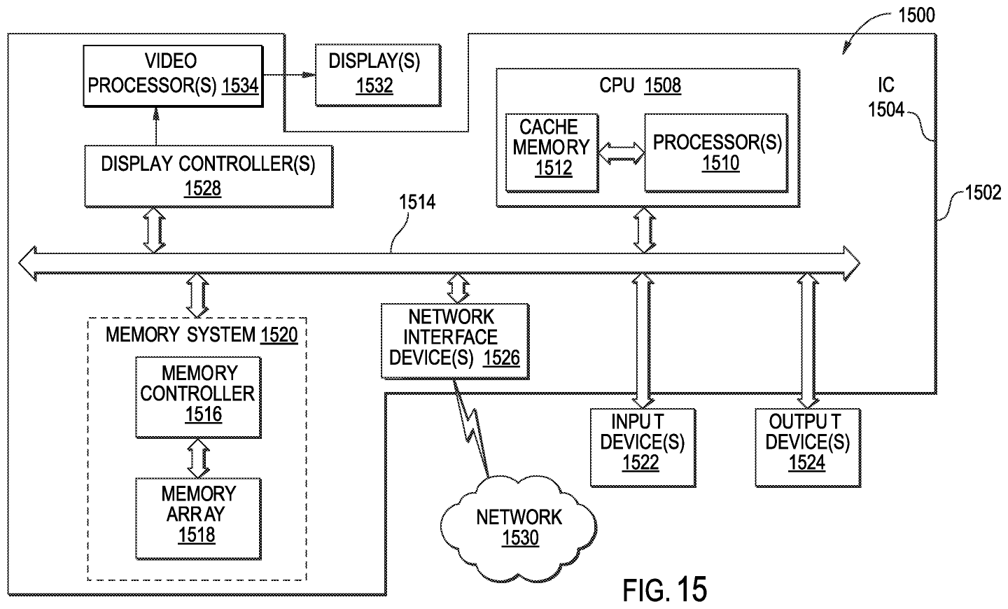

FIG. 15 illustrates a block diagram of an example of a processor-based system 1500 that may be implemented in the package substrate 500 in FIG. 5, including an IC package including a raised interconnect layer on a package substrate to reduce package interconnect dimensions and reduce the impedance of signal interconnects coupled to an IC in the IC package, such as any of the IC packages 800, 900, 1000, and 1100 in FIGS. 8-11B. In this example, the processor-based system 1500 includes a processor 1502 that includes an IC 1504 including one or more central processor units (CPUs) 1508, which may also be referred to as CPU or processor cores, each including one or more processors 1510. The CPU(s) 1508 may have cache memory 1512 coupled to the processor(s) 1502 for rapid access to temporarily stored data. The CPU(s) 1508 is coupled to a system bus 1514 and can intercouple master and slave devices included in the processor-based system 1500. As is well known, the CPU(s) 1508 communicates with these other devices by exchanging address, control, and data information over the system bus 1514. For example, the CPU(s) 1508 can communicate bus transaction requests to a memory controller 1516 as an example of a slave device. Although not illustrated in FIG. 15, multiple system buses 1514 could be provided wherein each system bus 1514 constitutes a different fabric.

Other master and slave devices can be connected to the system bus 1514. As illustrated in FIG. 15, these devices can include a memory system 1520 that includes the memory controller 1516 and one or more memory arrays 1518, one or more input devices 1522, one or more output devices 1524, one or more network interface devices 1526, and one or more display controllers 1528, as examples. The input device(s) 1522 can include any type of input device, including, but not limited to, input keys, switches, voice processors, etc. The output device(s) 1524 can include any type of output device, including, but not limited to, audio, video, other visual indicators, etc. The network interface device(s) 1526 can be any device configured to allow an exchange of data to and from a network 1530. The network 1530 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1526 can be configured to support any type of communications protocol desired.

The CPU(s) 1508 may also be configured to access the display controller(s) 1528 over the system bus 1514 to control information sent to one or more displays 1532. The display controller(s) 1528 sends information to the display(s) 1532 to be displayed via one or more video processors 1534, which process the information to be displayed into a format suitable for the display(s) 1532. The display(s) 1532 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read-Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A substrate comprising:
   a surface interconnect layer comprising a plurality of surface interconnects extending between a first area and a second area on a first surface, the first area configured to couple to an integrated circuit (IC) die;
   a dielectric layer disposed on the surface interconnect layer in the second area; and
   a raised interconnect layer disposed on the dielectric layer and comprising a plurality of raised interconnects coupled to the plurality of surface interconnects through the dielectric layer.
2. The substrate of clause 1, wherein:
   the plurality of surface interconnects comprises a first surface interconnect extending from a first location in the second area to a second location in the second area; and
   the plurality of raised interconnects comprise a first raised interconnect coupled to the first surface interconnect in the first location and in the second location.
3. The substrate of clause 2, further comprising:
   a first via extending through the dielectric layer to couple the first surface interconnect to the first raised interconnect in the first location; and
   a second via extending through the dielectric layer to couple the first surface interconnect to the first raised interconnect in the second location.
4. The substrate of clause 1, wherein the second area is on a perimeter of the first area.
5. The substrate of any of clause 1 to clause 3, the first surface further comprising a third area between the second area and an edge of the substrate, wherein the dielectric layer is not disposed in the third area.
6. The substrate of any of clause 1 to clause 4, wherein the dielectric layer extends from the perimeter of the first area to an edge of the substrate.
7. The substrate of any of clause 1 to clause 6, the raised interconnect layer further comprising package contacts coupled to the plurality of raised interconnects and configured to couple to package interconnects further coupled to a second substrate.
8. The substrate of any of clause 2 to clause 7, wherein one of the package contacts is disposed in the second location.
9. The substrate of any of clause 1 to clause 8, wherein a first center-to-center distance between two adjacent surface interconnects of the plurality of surface interconnects in the first area is greater than a second center-to-center distance between the two adjacent surface interconnects in the second area.
10. The substrate of any of clause 1 to clause 9, wherein a first width of the first surface interconnect of the plurality of surface interconnects in the first area is greater than a second width of the first surface interconnect in the second area.
11. A package comprising:
   a first integrated circuit (IC) die disposed in a first area of a first surface of a package substrate;
   a surface interconnect layer comprising a plurality of surface interconnects coupled to the first IC die and extending to a second area of the first surface of the package substrate;
   a dielectric layer disposed on the surface interconnect layer in the second area of the package substrate; and
   a raised interconnect layer disposed on the dielectric layer and comprising a plurality of raised interconnects coupled to the plurality of surface interconnects through the dielectric layer.
12. The package of clause 11, wherein:
   the plurality of surface interconnects comprises a first surface interconnect extending from a first location in the second area to a second location in the second area; and
   the plurality of raised interconnects comprise a first raised interconnect coupled to the first surface interconnect in the first location and in the second location.
13. The package of clause 11 or clause 12, the raised interconnect layer further comprising package contacts on the dielectric layer and electrically coupled to the plurality of raised interconnects coupled to the first IC die.
14. The package of clause 13, further comprising a second substrate coupled to the package contacts on the dielectric layer, the first IC die disposed between the package substrate and the second substrate.
15. The package of clause 13 or clause 14, wherein:
   a first distance from the package contacts to the second substrate in a first direction is less than a second distance from the surface interconnect layer to the second substrate in the first direction.
16. The package of clause 11 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
17. A method of fabricating a package, the method comprising:
   forming a package substrate comprising a surface interconnect layer comprising a plurality of surface interconnects extending between a first area and a second area of a first surface of the package substrate;
   disposing a first integrated circuit (IC) die in the first area and coupled to the plurality of surface interconnects;
   forming a dielectric layer on the surface interconnect layer in the second area; and
   forming a raised interconnect layer on the dielectric layer and comprising a plurality of raised interconnects coupled to the plurality of surface interconnects through the dielectric layer.
18. The method of clause 17, further comprising:
   forming two adjacent surface interconnects of the plurality of surface interconnects having a first center-to-center distance in the first area and a second center-to-center distance between the two adjacent surface interconnects in the second area, the second center-to-center distance less than the first center-to-center distance.
19. The method of clause 17 or clause 18, further comprising:
   forming a first vertical interconnect access (via) through the dielectric layer to couple one of the plurality of surface interconnects to one of the plurality of raised interconnects in a first location; and forming a second via through the dielectric layer to couple the one of the plurality of surface interconnects to the one of the plurality of raised interconnects in a second location.
20. The method of any of clause 17 to clause 19, further comprising:
   forming package contacts on the dielectric layer and coupled to the plurality of raised interconnects;
   forming package interconnects on the package contacts; and
   disposing a second substrate on the package interconnects.

What is claimed is:

1. A substrate comprising:
a surface interconnect layer comprising a plurality of surface interconnects extending between a first area and a second area on a first surface, the first area configured to couple to an integrated circuit (IC) die;
a dielectric layer disposed on the surface interconnect layer in the second area; and
a raised interconnect layer disposed on the dielectric layer and comprising a plurality of raised interconnects coupled to the plurality of surface interconnects through the dielectric layer.

2. The substrate of claim 1, wherein:
the plurality of surface interconnects comprises a first surface interconnect extending from a first location in the second area to a second location in the second area; and
the plurality of raised interconnects comprise a first raised interconnect coupled to the first surface interconnect in the first location and in the second location.

3. The substrate of claim 2, further comprising:
a first via extending through the dielectric layer to couple the first surface interconnect to the first raised interconnect in the first location; and
a second via extending through the dielectric layer to couple the first surface interconnect to the first raised interconnect in the second location.

4. The substrate of claim 1, wherein the second area is on a perimeter of the first area.

5. The substrate of claim 1, the first surface further comprising a third area between the second area and an edge of the substrate, wherein the dielectric layer is not disposed in the third area.

6. The substrate of claim 4, wherein the dielectric layer extends from the perimeter of the first area to an edge of the substrate.

7. The substrate of claim 2, the raised interconnect layer further comprising package contacts coupled to the plurality of raised interconnects and configured to couple to package interconnects further coupled to a second substrate.

8. The substrate of claim 7, wherein one of the package contacts is disposed in the second location.

9. The substrate of claim 1, wherein a first center-to-center distance between two adjacent surface interconnects of the plurality of surface interconnects in the first area is greater than a second center-to-center distance between the two adjacent surface interconnects in the second area.

10. The substrate of claim 2, wherein a first width of the first surface interconnect of the plurality of surface interconnects in the first area is greater than a second width of the first surface interconnect in the second area.

11. A package comprising:
a first integrated circuit (IC) die disposed in a first area of a first surface of a package substrate;
a surface interconnect layer comprising a plurality of surface interconnects coupled to the first IC die and extending to a second area of the first surface of the package substrate;
a dielectric layer disposed on the surface interconnect layer in the second area of the package substrate; and
a raised interconnect layer disposed on the dielectric layer and comprising a plurality of raised interconnects coupled to the plurality of surface interconnects through the dielectric layer.

12. The package of claim 11, wherein:
the plurality of surface interconnects comprises a first surface interconnect extending from a first location in the second area to a second location in the second area; and
the plurality of raised interconnects comprise a first raised interconnect coupled to the first surface interconnect in the first location and in the second location.

13. The package of claim 11, the raised interconnect layer further comprising package contacts on the dielectric layer and electrically coupled to the plurality of raised interconnects coupled to the first IC die.

14. The package of claim 13, further comprising a second substrate coupled to the package contacts on the dielectric layer, the first IC die disposed between the package substrate and the second substrate.

15. The package of claim 14, wherein:
a first distance from the package contacts to the second substrate in a first direction is less than a second distance from the surface interconnect layer to the second substrate in the first direction.

16. The package of claim 11 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

17. A method of fabricating a package, the method comprising:
forming a package substrate comprising a surface interconnect layer comprising a plurality of surface interconnects extending between a first area and a second area of a first surface of the package substrate;
disposing a first integrated circuit (IC) die in the first area and coupled to the plurality of surface interconnects;
forming a dielectric layer on the surface interconnect layer in the second area; and
forming a raised interconnect layer on the dielectric layer and comprising a plurality of raised interconnects coupled to the plurality of surface interconnects through the dielectric layer.

18. The method of claim 17, further comprising:
forming two adjacent surface interconnects of the plurality of surface interconnects having a first center-to-center distance in the first area and a second center-to-center distance between the two adjacent surface interconnects in the second area, the second center-to-center distance less than the first center-to-center distance.

19. The method of claim 17, further comprising:
forming a first vertical interconnect access (via) through the dielectric layer to couple one of the plurality of surface interconnects to one of the plurality of raised interconnects in a first location; and
forming a second via through the dielectric layer to couple the one of the plurality of surface interconnects to the one of the plurality of raised interconnects in a second location.

20. The method of claim 17, further comprising:
forming package contacts on the dielectric layer and coupled to the plurality of raised interconnects;
forming package interconnects on package contacts; and
disposing a second substrate on the package interconnects.
